(19) United States
(12) Patent Application Publication
(10) Pub. No.: US 2007/0090382 A1
(43) Pub. Date: Apr. 26, 2007

(54) Light emitting diode package

(75) Inventor: Yung Ho Ryu, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/543,232

(22) Filed: Oct. 5, 2006

(30) Foreign Application Priority Data
Oct. 20, 2005 (KR) 10-2005-0099327

(51) Int. Cl. H01L 33/00

(52) U.S. Cl. 257/98

(57) ABSTRACT

A light emitting diode package is provided. A package body has a mounting part surrounded by side walls and lead electrodes on a bottom surface of the mounting part. A light emitting diode chip is mounted on the bottom surface of the mounting part and electrically connected to the lead electrodes. A resin encapsulant is filled in the mounting part to encapsulate the light emitting diode chip. At least one residual resin storage is formed on a top surface of a corresponding one of the side walls to guide and accommodate a residual resin for forming the encapsulant of a preset height. Further, a storing groove is formed on the top surface of the corresponding side wall and a guiding groove is formed to guide the residual resin to the storing groove. This produces the light emitting diode package with uniform color distribution regardless of a liquid resin amount injected.

### CLAIM OF PRIORITY

This application claims the benefit of Korean Patent Application No. 2005-99327 filed on Oct. 20, 2005 in the Korean Intellectual Property Office, the disclosure of which is incorporated herein by reference.

### BACKGROUND OF THE INVENTION

1. Field of the Invention

The present invention relates to a light emitting diode package, more particularly in which resin is coated to encapsulate a light emitting diode chip.

2. Description of the Related Art

In general, a light emitting diode is advantageous in terms of a superior monochromatic peak wavelength and light efficiency, and compactness. The light emitting diode is widely utilized in various display devices and as light sources. Here, the light emitting diode is mainly packaged. Especially the light emitting diode has been actively developed as a high efficiency and high output light source which can replace a back light of lighting devices and display devices.

FIG. 1 is a cross-sectional view illustrating a conventional light emitting diode package.

Referring to FIG. 1, the light emitting diode package 10 includes a package body 11 and a light emitting diode chip 17. The package body 11 has a mounting part 12 formed therein to seat the light emitting diode chip 17. Also, a reflecting surface 15 is formed on side walls which surround the mounting part 12. Lead electrodes 13 and 14 are disposed on a bottom surface of the mounting part 12 and electrically connected to the light emitting diode chip 17 mounted in the package via wires. The light emitting diode chip 17 mounted is encapsulated by a resin encapsulant 19 made of an epoxy resin or a silicone resin.

To produce an output light of a desired wavelength, the resin encapsulant 19 has phosphor particles dispersed therein. For example, YAG-based yellow phosphor particles may be dispersed in the silicone resin.

To manufacture such a conventional light emitting diode package 10, a dispenser needle is mostly used to inject a liquid resin (especially, with phosphor particles dispersed therein) into the mounting part 12.

The dispenser needle causes the liquid resin to be injected at an uneven amount, thus preventing the final resin encapsulant 19 from maintaining a uniform height.

This uneven thickness in the resin encapsulant 19 leads to different levels of wavelength conversion and uneven color distribution when a phosphor for converting a wavelength is employed.

In this conventional light emitting diode package, the liquid resin injected is not uniform in its surface height and accordingly in color distribution for each package. This results in a considerable amount of defective products, thereby hampering mass-producibility.

### SUMMARY OF THE INVENTION

The present invention has been made to solve the foregoing problems of the prior art and therefore an object according to certain embodiments of the present invention is to provide a light emitting diode package which has a resin encapsulant of a predetermined height regardless of differences in a liquid resin amount injected.

According to an aspect of the invention for realizing the object, there is provided a light emitting diode package including a package body having a mounting part surrounded by side walls and lead electrodes on a bottom surface of the mounting part; a light emitting diode chip mounted on the bottom surface of the mounting part and electrically connected to the lead electrodes; a resin encapsulant filled in the mounting part to encapsulate the light emitting diode chip; and at least one residual resin storage formed on a top surface of a corresponding one of the side walls to guide and accommodate a residual resin for forming the encapsulant of a preset height.

The residual resin storage includes a storing groove formed on the top surface of the corresponding side wall of the package body to store the residual resin, and a guiding groove formed between the mounting part and the storing groove to guide the residual resin from the mounting part to the storing groove, and a bottom surface of the storing groove is lower than the preset height of the resin encapsulant, and a bottom surface of the guiding groove is lower than another one of the side walls and equal to the preset height of the resin encapsulant.

The bottom surface of the guiding groove is equal to an actual height of the resin encapsulant.

A plurality of storing grooves are disposed on the opposing side walls.

Each of the storing grooves is formed on each of the opposing side walls.

The storing groove has a width greater than that of the guiding groove.

The storing groove has a width equal to that of the guiding groove. The storing.groove has a planar shape selected from a group consisting of square, rectangle and circle.

The resin encapsulant includes a phosphor for converting a wavelength of a light generated from the light emitting diode chip.

The light emitting diode chip comprises a blue light emitting diode chip, and the resin encapsulant includes a yellow phosphor for converting the wavelength of the light generated from the blue light emitting diode chip.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side sectional view illustrating a conventional light emitting diode package;

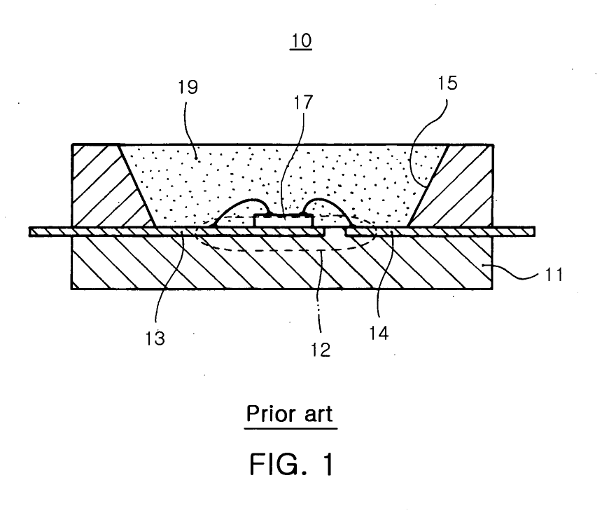

FIG. 2a is a side sectional view illustrating a light emitting diode package according to an embodiment of the invention;

FIG. 2b is a top plan view illustrating the light emitting diode package shown in FIG. 2a;

FIG. 3 is a schematic view illustrating flow of a residual resin when a liquid resin is supplied excessively in a package structure of FIG. 2b;

FIG. 4a is a side sectional view illustrating a light emitting diode package according to another embodiment of the invention;

FIG. 4b is a top plan view illustrating the light emitting diode package shown in FIG. 4a;

FIG. 5a is a side sectional view illustrating a light emitting diode package according to further another embodiment of the invention; and

FIG. 5b is a top plan view illustrating the light emitting diode package shown in FIG. 5a.

### DETAILED DESCRIPTION OF THE PREFERRED EMBODIMENT

Preferred embodiments of the present invention will now be described in detail with reference to the accompanying drawings.

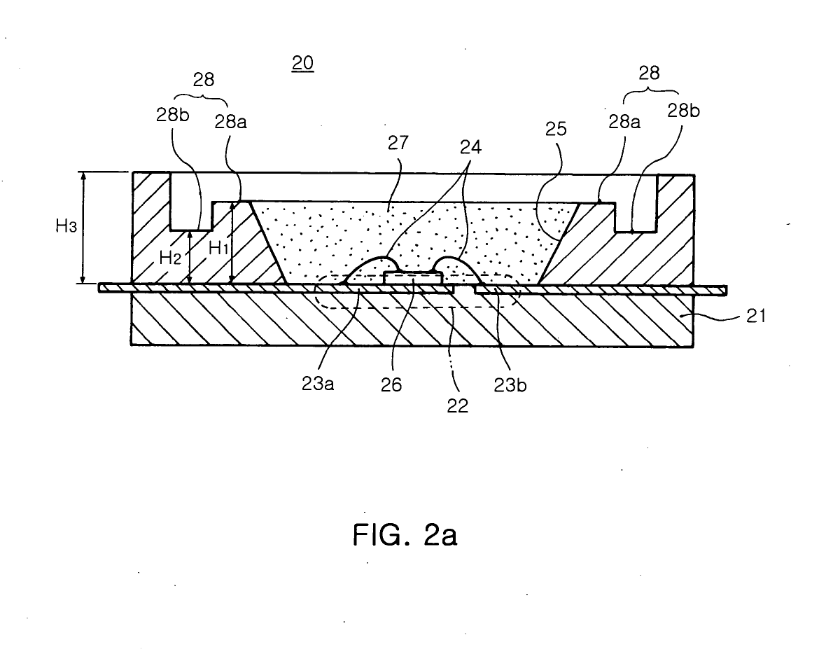

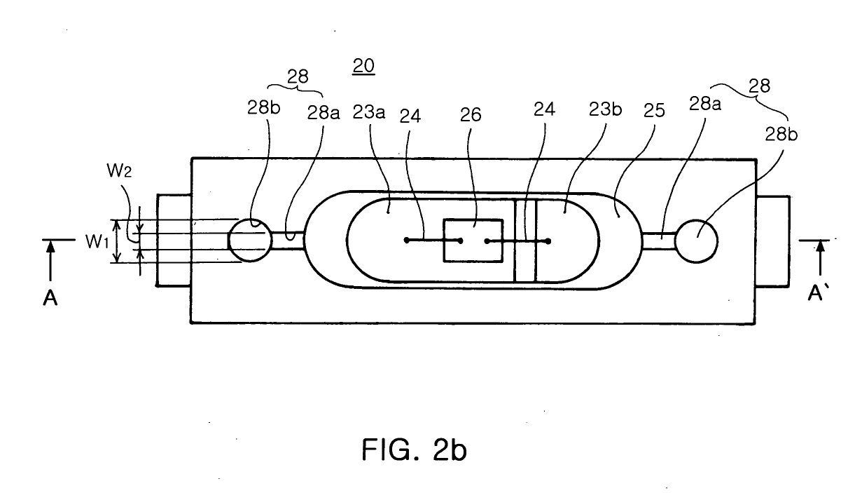

FIG. 2a is a side sectional view illustrating a light emitting diode package according to an embodiment of the invention and FIG. 2b is a top plan view illustrating the light emitting diode package shown in FIG. 2a. Herein, FIG. 2a is a side sectional view taken along the line A-A′ of FIG. 2a.

First, referring to FIG. 2a, the light emitting diode package 20 includes a mounting area 22 surrounded by side walls. Preferably, the side walls each include a reflecting surface 25 inclined from a top surface of a corresponding one of the side walls to a bottom surface of the mounting area 22 to enhance brightness.

The light emitting diode package 20 includes lead electrodes 23a and 23b, a light emitting diode chip 26 and a resin encapsulant 27. The lead electrodes 23a and 23b are disposed on the bottom surface of the mounting part 22. A light emitting diode chip 26 is mounted on the bottom surface of the mounting part 22 and electrically connected to the lead electrodes 23a and 23b by wires 24. The resin encapsulant 27 is filled in the mounting part 22 to encapsulate the light emitting diode chip 26.

In this embodiment, the lead electrodes 23a and 23b are protruded from sides of the package body 21 to connect a metal wiring structure connected to the light emitting diode chip 26 to the outside. Alternatively, the light emitting diode package 20 may include the lead electrodes extended to a lowest end along the package body, a via and a bonding pad formed on upper and lower ends of the package body to be connected to the via.

The light emitting diode package 20 according to this embodiment includes residual resin storages 28 formed on corresponding ones of the side walls of the package body 21.

Referring to FIGS. 2a and 2b, the residual resin storages 28 shown according to the invention each include a storing groove 28b and a guiding groove 28a. The storing groove 28b is formed on the corresponding side wall to store the residual resin. The guiding groove 28a is formed between the mounting part 22 and the storing groove 28b to guide the residual resin from the mounting part 22 to the storing groove 28b.

A bottom surface of the storing groove 28b has a height H2 smaller than a preset height of the resin encapsulant 27. A bottom surface of the guiding groove 28a has a height H1 smaller than a height H3 of another one of the side walls and equal to the preset height of the resin encapsulant 27.

Of course, preferably, as shown, the bottom surface of the guiding groove 28b has a height H1 equal to an actual height of the resin encapsulant 27.

Herein, a ‘preset height’ denotes a desired height of the resin encapsulant. According to the invention, the bottom surface of the guiding groove has a height H1 equal to or higher than that of the resin encapsulant.

The guiding groove 28a has a width W2 smaller than a width W1 of the storing groove 28b. In another embodiment of the invention, the width W2 of the guiding groove 28a is equal to the width W1 of the storing groove 28b.

The storing grooves 28b may be disposed on the opposing side walls of the package body 21.

In further another embodiment of the invention, the storing grooves may be formed on other corresponding ones of the side walls having greater lengths. However, in general, the top surfaces of the side walls having smaller lengths have sufficient areas to form the storing grooves for gathering more residual resin amount in the package according to this embodiment.

The storing grooves 28b may be formed on each of the opposing side walls.

In another embodiment, a plurality of storing grooves and subsequently a plurality of guiding grooves may be formed on the opposing side walls. However, typically, as in the package according to the invention, one storing groove and one guiding groove are formed on each of the opposing side walls, thereby beneficially utilizing a limited package space and thus further miniaturizing the package.

Also, according to various embodiments, the storing groove 28b has a planar shape selected from square, rectangle and circle but is not limited thereto.

The resin encapsulant 27 may include a phosphor for converting a wavelength of a light generated from the light emitting diode chip 26.

For example, to produce a white light emitting diode package, the light emitting diode chip 26 is a blue light emitting diode chip. Also, the resin encapsulant 27 may include a yellow phosphor for converting the wavelength of the light generated from the blue light emitting diode chip.

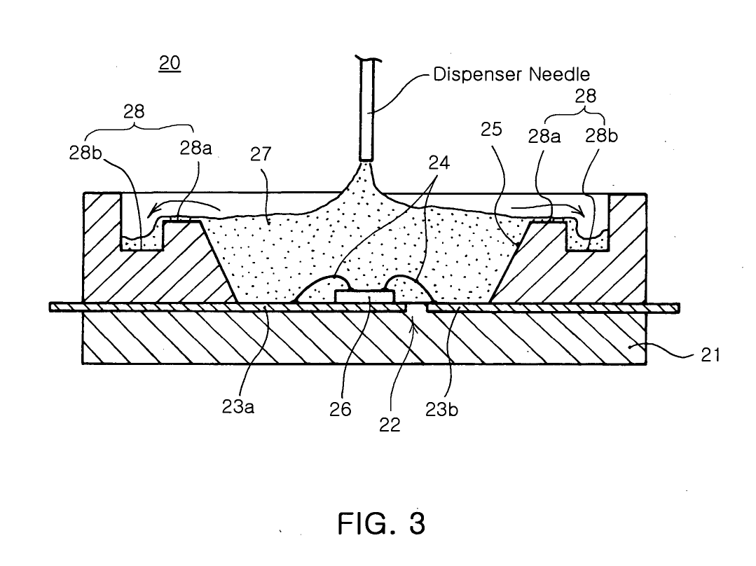

FIG. 3 is a schematic view illustrating flow of a residual resin when a liquid resin is supplied excessively in a package structure of FIG. 2b.

Referring to FIG. 3, in the light emitting diode package 20 of the invention, the liquid resin is injected by a dispenser needle to encapsulate the light emitting diode chip 26. Preferably, a preset height of the resin encapsulant 27 filled with the liquid resin is equal to an actual height thereof. Yet, the liquid resin amount injected may exceed the preset height due to errors resulting from the dispenser needle itself. Here, the residual resin injected is flown along a guiding groove 28a of a residual resin storage 28 to a storing groove 28b so that the preset height of the resin encapsulant 27 can be equal to an actual height thereof.

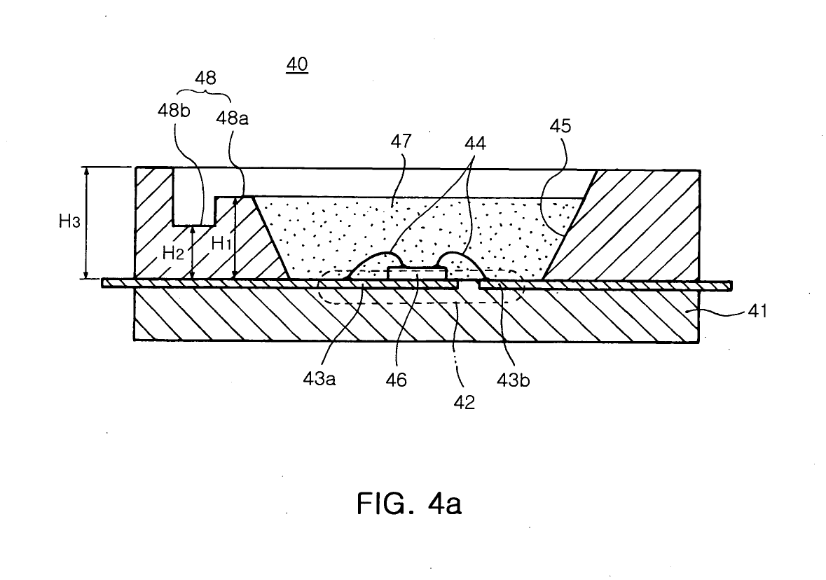

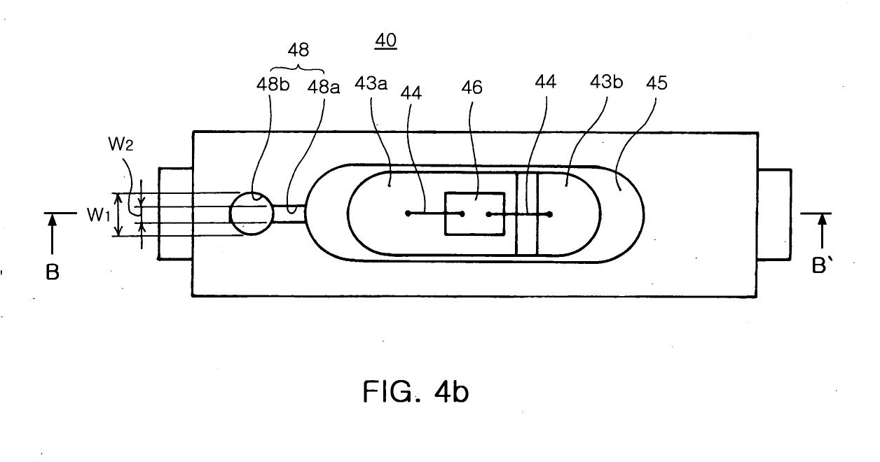

FIG. 4a is a side sectional view illustrating a light emitting diode package according to another embodiment of the invention and FIG. 4b is a top plan view illustrating the light emitting diode package shown in FIG. 4a. Herein, FIG. 4a is a side sectional view taken along the line B-B′ of FIG. 4b.

Referring to FIG. 4a, the light emitting diode package 40 according to another embodiment of the invention has a mounting part surrounded by side walls, which each may include a reflecting surface 45.

The light emitting diode package 40 includes lead electrodes 43a and 43b, a light emitting diode chip 46 and a resin encapsulant 47. The lead electrodes 43a and 43b are disposed on a bottom surface of the mounting part 42. The light emitting diode chip 46 is mounted on the bottom surface of the mounting part 42 and electrically connected to the lead electrodes 43a and 43b by wires 44. The resin encapsulant 47 is filled in the mounting part 42 to encapsulate the light emitting diode chip.

The light emitting diode package 40 according to this embodiment includes a residual resin storage 48 formed on a corresponding one of the side walls of the package body 41.

In this embodiment, the light emitting diode package 40 includes only one residual resin storage 48. Referring to FIGS. 4a and 4b, the light emitting diode package 40 includes a storing groove 48b formed on the package to store a residual resin and a guiding groove 48a formed between the mounting part 42 and the storing groove 48b to guide the residual resin from the mounting part 42 to the storing groove 48b.

As shown, the guiding groove 48a may have a width W2 smaller than a width Wl of the storing groove 48b.

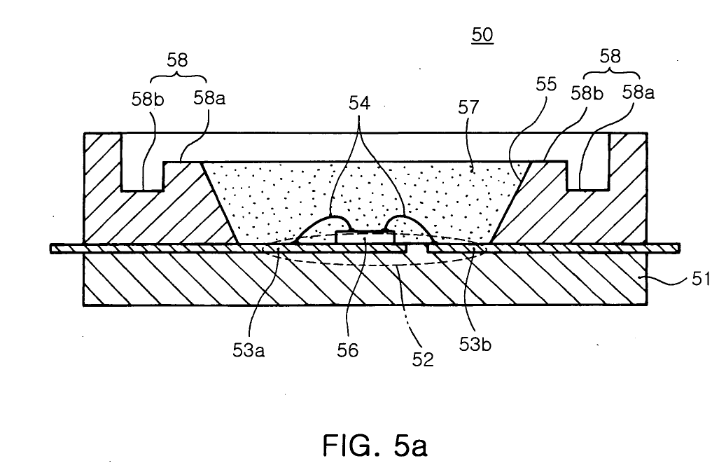

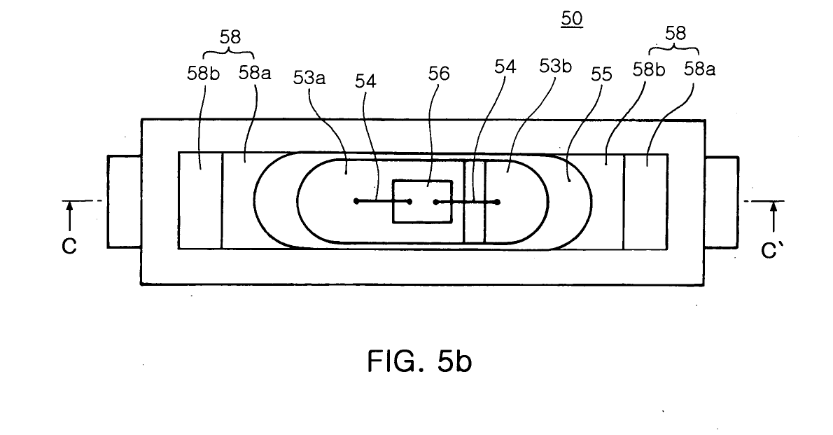

FIG. 5a is a side sectional view illustrating a light emitting diode package according to further another embodiment of the invention and FIG. 5b is a top plan view illustrating the light emitting diode package shown in FIG. 5a. Herein, FIG. 5a is a side sectional view taken along the line C-C′ of FIG. 5b.

Referring to FIG. 5a, the light emitting diode package 50 according to another embodiment of the invention has a mounting part 52 surrounded by side walls, which each may include a reflecting surface 55.

The light emitting diode package 50 includes lead electrodes 53aand 53b, a light emitting diode chip 56 and a resin encapsulant 57. The lead electrodes 53a and 53b are disposed on a bottom surface of the mounting part 52. The light emitting diode chip 56 is mounted on the bottom surface of the mounting part 52 and electrically connected to the lead electrodes 53a and 53b by wires 54. The resin encapsulant 57 is filled in the mounting part 52 to encapsulate the light emitting diode chip.

The light emitting diode package of this embodiment includes residual resin storages 58 each formed on a corresponding one of side walls of the package body 51.

Referring to FIGS. 5a and 5b, the residual resin storage 58 of this embodiment includes storing grooves 58b each formed on the side wall of the package to store a residual resin and guiding grooves 58a each formed between the mounting part 52 and the storing groove 58b to guide the residual resin from the mounting part 52 to the storing groove 58b. In the residual resin storage 58, a width of the guiding grooves 58a for guiding the residual resin to the storing groove 58b may be equal to a width of the storing groove 58b, thereby guiding and storing the residual resin more easily. However the invention is not limited thereto.

As set forth above, according to preferred embodiments of the invention, a storing groove is formed on a side wall of a light emitting diode package and a guiding groove is formed to guide a residual resin to the storing groove. Therefore, when a liquid resin injected exceeds a preset height of a resin encapsulant, the residual resin is guided to the storing groove. This produces a light emitting diode package with uniform color distribution regardless of the liquid resin amount injected.

While the present invention has been shown and described in connection with the preferred embodiments, it will be apparent to those skilled in the art that modifications and variations can be made without departing from the spirit and scope of the invention as defined by the appended claims.

What is claimed is:

1. A light emitting diode package comprising:
a package body having a mounting part surrounded by side walls and lead electrodes on a bottom surface of the mounting part;
a light emitting diode chip mounted on the bottom surface of the mounting part and electrically connected to the lead electrodes;
a resin encapsulant filled in the mounting part to encapsulate the light emitting diode chip; and
at least one residual resin storage formed on a top surface of a corresponding one of the side walls to guide and accommodate a residual resin for forming the encapsulant of a preset height.

2. The light emitting diode package according to claim 1, wherein the residual resin storage includes a storing groove formed on the top surface of the corresponding side wall of the package body to store the residual resin, and a guiding groove formed between the mounting part and the storing groove to guide the residual resin from the mounting part to the storing groove, and
wherein a bottom surface of the storing groove is lower than the preset height of the resin encapsulant, and a bottom surface of the guiding groove is lower than another one of the side walls and equal to the preset height of the resin encapsulant.

3. The light emitting diode package according to claim 2, wherein the bottom surface of the guiding groove is equal to an actual height of the resin encapsulant.

4. The light emitting diode package according to claim 2, wherein a plurality of storing grooves are disposed on the opposing side walls of the package body.

5. The light emitting diode package according to claim 4, wherein each of the storing grooves is formed on each of the opposing side walls.

6. The light emitting diode package according to claim 2, wherein the storing groove has a width greater than that of the guiding groove.

7. The light emitting diode package according to claim 2, wherein the storing groove has a width equal to that of the guiding groove.

8. The light emitting diode package according to claim 2, wherein the storing groove has a planar shape selected from a group consisting of square, rectangle and circle.

9. The light emitting diode package according to claim 1, wherein the resin encapsulant includes a phosphor for converting a wavelength of a light generated from the light emitting diode chip.

10. The light emitting diode package according to claim 2, wherein the resin encapsulant includes a phosphor for converting a wavelength of a light generated from the light emitting diode chip.

11. The light emitting diode package according to claim 3, wherein the resin encapsulant includes a phosphor for converting a wavelength of a light generated from the light emitting diode chip.

12. The light emitting diode package according to claim 5, wherein the resin encapsulant includes a phosphor for converting a wavelength of a light generated from the light emitting diode chip.

13. The light emitting diode package according to claim 9, wherein the light emitting diode chip comprises a blue light emitting diode chip, and the resin encapsulant includes a yellow phosphor for converting the wavelength of the light generated from the blue light emitting diode chip.

14. The light emitting diode package according to claim 10, wherein the light emitting diode chip comprises a blue light emitting diode chip, and the resin encapsulant includes a yellow phosphor for converting the wavelength of the light generated from the blue light emitting diode chip.

15. The light emitting diode package according to claim 11, wherein the light emitting diode chip comprises a blue light emitting diode chip, and the resin encapsulant includes a yellow phosphor for converting the wavelength of the light generated from the blue light emitting diode chip.

16. The light emitting diode package according to claim 12, wherein the light emitting diode chip comprises a blue light emitting diode chip, and the resin encapsulant includes a yellow phosphor for converting the wavelength of the light generated from the blue light emitting diode chip.
